(19) United States
(12) Patent Application Publication
(10) Pub. No.: US 2006/0105477 A1
(43) Pub. Date: May 18, 2006

(54) Device and method for manufacturing wafer-level package

(76) Inventors: Suk-Kun Lim, Chungcheongnam-do (KR); Chae-Hun Im, Chungcheongnam-do (KR); Min-Ill Kim, Chungcheongnam-do (KR); Chang-Cheol Lee, Chungcheongnam-do (KR)

Correspondence Address: MARGER JOHNSON & MCCOLLOM, P.C., 210 SW MORRISON STREET, SUITE 400, PORTLAND, OR, 97204, US

(21) Appl. No.: 11/280,838

(22) Filed: Nov. 15, 2005

(30) Foreign Application Priority Data
Nov. 15, 2004 (KR) 2004-93002

(51) Int. Cl. H01L 21/66; G01R 31/26

(52) U.S. Cl. 438/15

(57) ABSTRACT

In an embodiment of the invention, a device for manufacturing a wafer-level package includes a wafer sawing unit, a sorting unit, a pickup unit, and a placing unit. The wafer sawing unit cuts a wafer into wafer-level packages. The sorting unit performs a sorting process on the wafer-level packages to judge whether each of the wafer-level packages is normal or not. The pickup unit picks up the normal wafer-level packages. The placing unit stores the normal wafer-level packages in a storage case. The sawing process, the sorting process, and the placing process for the wafer-level package can be automatically performed within one device, thus a processing time reduction, a processing accuracy increase, and manpower reduction are achieved compared with the case where the processes are performed manually.

### BACKGROUND OF THE INVENTION

This application claims the priority of Korean Patent Application No. 10-2004-0093002, filed on Nov. 15, 2004, in the Korean Intellectual Property Office, the disclosure of which is incorporated herein in its entirety by reference.

1. Field of the Invention

The present invention relates to a device and method for manufacturing a semiconductor, and more particularly, to a device and method for manufacturing a wafer-level package.

2. Description of the Related Art

Recently, interest has increased in wafer-level package technology for the small-sizing trend of semiconductor devices. Unlike related art technology in which chips cut from a wafer are packaged one by one, recent wafer-level package technology includes assembling on a wafer level where chips are not separated. Generally, four processes are required in manufacturing one semiconductor: namely, circuit design, wafer processing, assembling, and inspection. Among those processes, the assembling process includes a wire connection and a package operation, and has been a process in which chips are first cut from a process-completed wafer. The cut chips are respectively attached to a small circuit board, the wires are connected, and then each chip is covered with a plastic package. On the contrary, according to the wafer package technology, a package process is completed by a simple procedure in which a photosensitive insulation material, instead of the plastics which has been used for a package material, is spread on each chip of the wafer, wirings are connected, and then the insulation material is put thereon. By applying the wafer-level package technology, a plastic, a circuit board, and a wire for a wiring connection which have been used for a semiconductor assembling process in a related art are not required any more, thus manufacturing costs can be greatly reduced. Particularly, since a package having the same size as the chip can be manufactured, a final package size can be reduced more than 20% compared with a conventional chip scale package (CSP). Therefore, since it is possible to mount more chips on a memory module of the same size, manufacturing a memory module of a large capacity requires less effort.

In the wafer-level package, after a packaging process is completed on the wafer, a sawing process for separating individual wafer-level packages on the wafer is performed. After that, a pickup and placing process for discriminating and positioning normal wafer-level packages and bad wafer-level package should be performed. In the related art, the sawing process has been performed using a separate sawing device. On the contrary, the pickup and placing process has been performed manually. Accordingly, damage may occur by human handling and discrimination cannot be accurately performed, depending on an operator.

### SUMMARY OF THE INVENTION

Embodiments of the present invention provide a wafer-level package manufacturing device capable of continuously and automatically performing a sawing process, a pickup process, and a placing process.

Also, embodiments of the present invention provide a wafer-level package manufacturing method capable of continuously and automatically performing a sawing process, a pickup process, and a placing process.

According to an embodiment of the present invention, there is provided a device for manufacturing a wafer-level package. The device includes: a wafer sawing unit; a sorting unit; a pickup unit; and a placing unit.

The device may further include: a wafer transferring unit arranged between the wafer sawing unit and the sorting unit.

The sorting unit may use an electronic vision system for a sorting process.

The pickup unit may include: a rail for moving and supporting the wafer; a lifter arranged at a lower portion of the rail; and a pickup part for picking up the wafer-level package raised up by the lifter.

According to another embodiment of the present invention, there is provided a device for manufacturing a wafer-level package. The device includes: a wafer sawing unit; a wafer transferring unit; a first sorting unit arranged on a first path; a first pickup unit arranged adjacently to the first sorting unit; a second sorting unit arranged on a second path; a second pickup unit arranged adjacent to the second sorting unit; and a placing unit.

According to still another embodiment of the present invention, there is provided a method for manufacturing a wafer-level package. The method includes: sawing a wafer into separate wafer-level packages; transferring the wafer-level packages; sorting the wafer-level packages based on whether the wafer-level packages are normal or not; picking up normal wafer-level packages; and storing the picked-up normal wafer-level packages in a storage case.

### BRIEF DESCRIPTION OF THE DRAWINGS

The above and other features and advantages of the present invention will become more apparent by describing in detail exemplary embodiments thereof with reference to the attached drawings, in which:

FIG. 1 is a plan view illustrating a device for manufacturing a wafer-level package according to an embodiment of the present invention;

FIG. 2 is a plan view illustrating a transfer unit of the wafer-level package manufacturing device shown in FIG. 1;

FIG. 3 is a perspective view illustrating a sorting unit of the wafer-level package manufacturing device shown in FIG. 1;

FIG. 4 is a side view illustrating a pickup unit a of the wafer-level package manufacturing device shown in FIG. 1; and

FIG. 5 is a side view illustrating a placing unit a of the wafer-level package manufacturing device shown in FIG. 1.

### DETAILED DESCRIPTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity. Like reference numerals in the drawings denote like elements, and thus their description will be omitted.

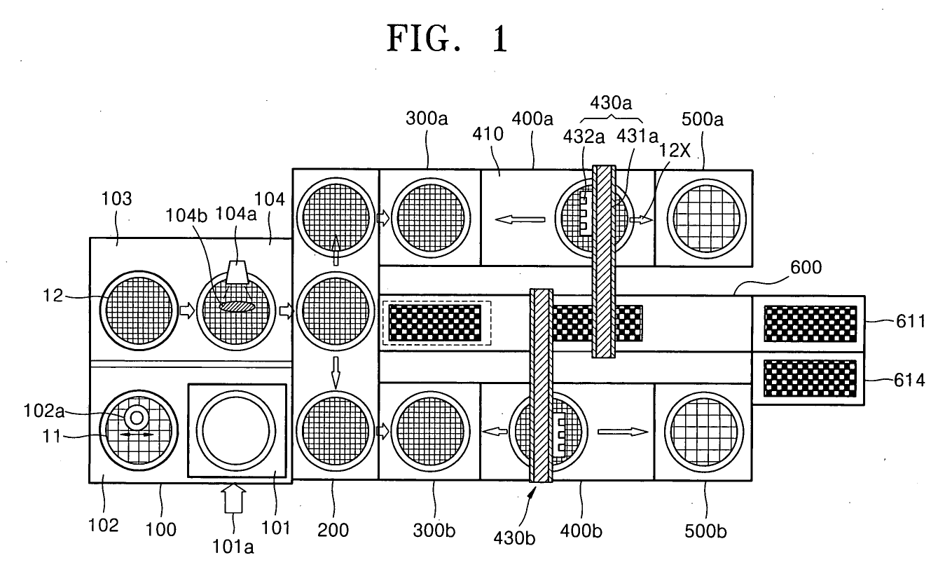

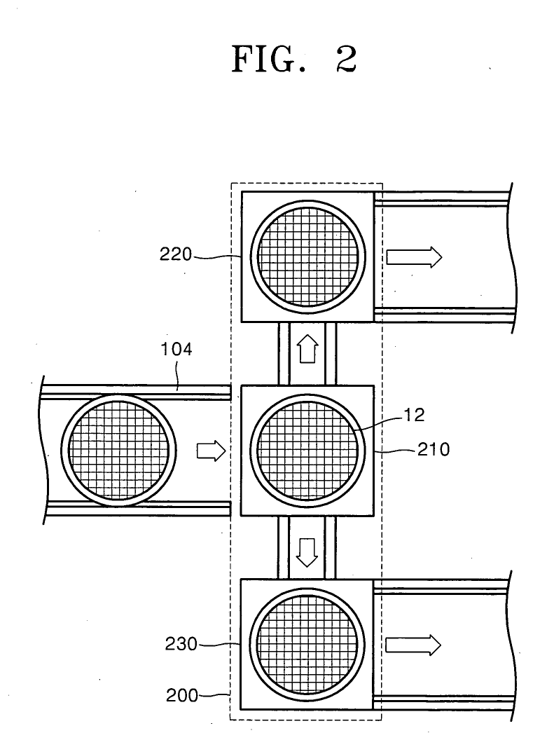

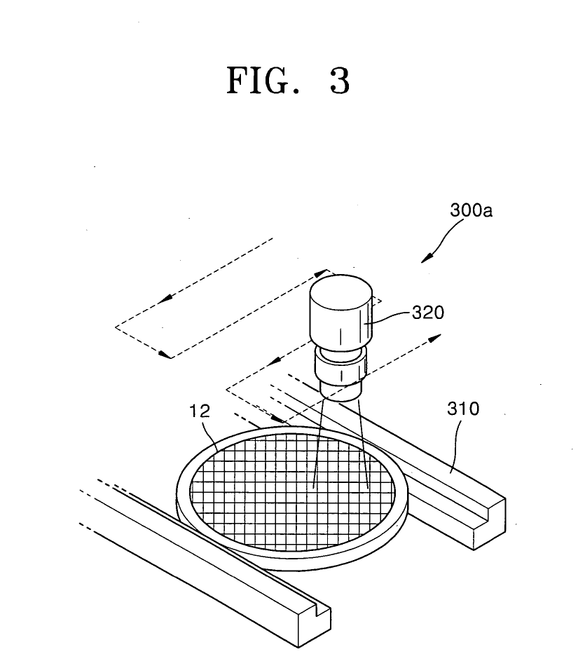

FIG. 1 illustrates a device for manufacturing a wafer-level package according to an embodiment of the present invention, FIG. 2 illustrates a transfer unit of the wafer-level package manufacturing device shown in FIG. 1, and FIG. 3 illustrates a sorting unit of the wafer-level package manufacturing device shown in FIG. 1.

Referring to FIG. 1, the wafer-level package manufacturing device includes a wafer sawing unit 100, a wafer transfer unit 200, first and second sorting units 300a and 300b, first and second pickup units 400a and 400b, first and second carrier standby units 500a and 500b, and a placing unit 600. The sawing unit 100 and the transfer unit 200 are sequentially arranged. The first sorting unit 300a, the first pickup unit 400a, and the first carrier standby unit 500a are sequentially aligned and extended from an upper side part of the transfer unit 200. The second sorting unit 300b, the second pickup unit 400b, and the second carrier standby unit 500b are sequentially aligned and extended from a lower side part of the transfer unit 200. The placing unit 600 is extended from a center side part of the transfer unit 200.

The wafer sawing unit 100 divides wafer-level packages into separate packages. The wafer sawing unit 100 includes, which are sequentially arranged, a loading part 101 into which a carrier (not shown) containing wafers is loaded, a sawing part 102 for sawing the wafer-level packages, a cleaning part 103 for removing impurities caused by a sawing process, and a UV (ultraviolet) irradiating part 104 for weakening an adhesive force between a tape and the wafer-level packages. In detail, the carrier containing completely-assembled wafers is loaded in the loading part 101 as shown by an arrow 101a. A wafer 11 loaded in the loading part 101 is transferred to the sawing part 102 by a robotic, or automated, system. The sawing part 102 saws the wafer 11 into separate chips, that is, respective wafer-level packages. A reference numeral “102a” indicates a sawing device for performing a sawing process, for example a blade. A sawed wafer 12 is then transferred to the cleaning part 103, and the cleaning part 103 removes particles generated during the sawing process. The cleaned wafer 12 is then transferred to the UV irradiating part 104, and the UV irradiating part 104 irradiates UV rays to the cleaned wafer 12. As stated previously, the UV rays weaken adhesives force between a tape and wafer-level packages, whereby a following pickup process can be easily performed. Reference numerals “104a” and “104b” respectively represent a UV irradiator and an optical system.

In this manner, the wafer 12 is transferred to the wafer transfer unit 200. The wafer transfer unit 200 selectively transfers the wafer 12 transferred from the sawing unit 100 to a first path or a second path. In detail, as shown in FIG. 2, the wafer 12, UV-irradiated by the UV irradiating part 104, is transferred to a standby part 210 of the wafer transfer unit 200. Separate wafer transfer paths are respectively provided at sides of the standby part 210. That is, a first path part 220 is arranged at one side of the standby part 210, and a second path part 230 is arranged at the other side of the standby part 210. Accordingly, the wafer 12 transferred to the standby part 210 can be transferred to the first path part 220 or to the second path part 230. The transfers of the wafer 12 to the first path part 220 or the second path part 230 are alternately preformed. That is, if a first wafer is transferred to the first path part 220, a second wafer is transferred to the second path part 230 and a third wafer is transferred to the first path part 220, and so on. For the transfers of the wafer 12 from the standby part 210 to the first path part 220 or the second path part 230, servo motors (not shown) may be arranged at lower parts of the first and second path parts 220 and 230.

A wafer transferred to the first path part 220 is sequentially transferred to the first sorting unit 300a, the first pickup unit 400a and the first carrier standby part 500a. Similarly, a wafer transferred to the second path part 230 is sequentially transferred to the second sorting unit 300b, the second pickup unit 400b and the second carrier standby unit 500b. A process during the transfer of the wafer to the first sorting unit 300a, the first pickup unit 400a, and the first carrier standby unit 500a is identical to a process during the transfer of the wafer to the second sorting unit 300b, the second pickup unit 400b and the second carrier standby unit 500b. Accordingly, for simplicity, only the process during the transfer of the wafer to the first sorting unit 300a, the first pickup unit 400a, and the first carrier standby unit 500a will now be described.

As shown in FIG. 3, the wafer 12 transferred to the first sorting unit 300a is positioned on a wafer supporting rail 310 of the first sorting unit 300a. In this state, a vision system 320 arranged at an upper part of the first sorting unit 300a sorts sawed wafer-level packages. The vision system 320 moves in a zigzag shape (shown by a dotted arrow) movable by an X-Y motor, while checking whether respective wafer-level packages on the wafer 12 are normal or not. Quality (normal or abnormal) data about wafer-level packages may be combined with similar data about wafer-level packages obtained earlier at a previous state, whereby a final quality data is obtained. Judging quality using a vision system 320, and comparing data collected from earlier sample wafer-level packages, is well within the means of one skilled in the art. As stated previously, a process of the wafer 12 in the second sorting unit 300b is performed identically as above.

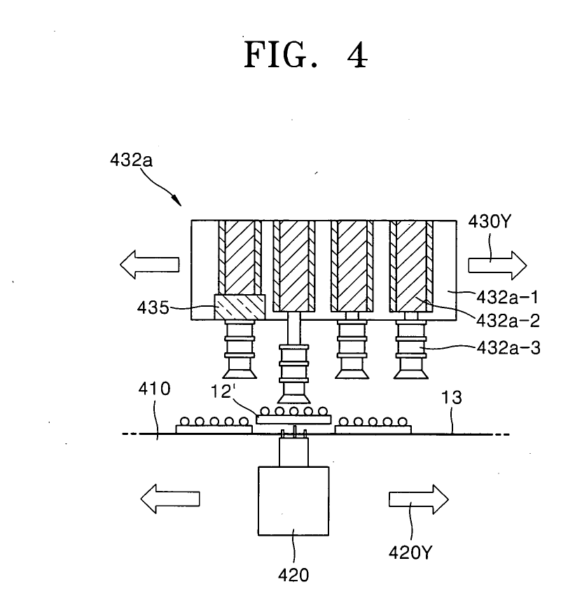

As shown in FIG. 4, the wafer 12 processed at the first sorting unit 300a is transferred to the first pickup unit 400a. The first pickup unit 400a includes a rail 410 for supporting and moving the transferred wafer 12, a lifter 420 arranged at a lower part of the rail 410 to push up a wafer-level package 12′ so that the wafer-level package 12′ can be easily separated from a tape 13, and a pickup part 430a for picking up the pushed-up wafer-level package 12′. The pickup part 430a includes a guide 431a arranged across the first pickup unit 400a and the placing unit 600, and a picker 432a arranged at a lower part of the guide 431a to pick up the wafer-level package 12′. Particularly, the picker 432a includes a frame 432a-1 for supporting the whole part, a supporter 432a-2 inserted into the frame 432a-1, and a pickup pad 432a-3 extended from the supporter 432a-2 and protruding toward a lower part of the frame 432a-1.

The lifter 420 is movable along a first direction denoted by an arrow 420Y of FIG. 4. Likewise, the picker 432a is also movable in the first direction denoted by an arrow 430Y of FIG. 4 along the guide 431a. That is, both the lifter 420 and the picker 432a are movable along the same first direction. However, the lifter 420 is movable along the first direction only within the first pickup unit 400a and the picker 432a is movable within both the first pickup unit 400a and the placing unit 600.

The wafer 12 moves to a second direction perpendicular to the movement direction of the lifter 420 and the picker 432a. The movement direction of the wafer 12 is denoted by an arrow 12X of FIG. 1. Specifically, the wafer 12 moves as much as a predetermined distance along the second direction denoted by the arrow 12X of FIG. 1 and stops. While the wafer 12 stops, the lifter 420 and the picker 432a move along the first direction and are respectively positioned at a backside and a front side of the wafer-level package 12′ to pick up the wafer-level package 12′ that has been judged as normal. With such a state, the lifter 420 raises the wafer-level package 12′ in a pushing manner from the back and the picker 432a picks up the raised wafer-level package 12′. At this point, as mentioned above, since the wafer-level package 12′ is in a state of being raised by the lifter 420, the wafer-level package 12′ is easily detached from the tape 13 on a backside of the wafer-level package 12′. The wafer-level package 12′ picked up by the picker 432a is placed in a storage case positioned in the placing unit 600 by the picker 432a. Description thereof will be made in detail later. The above-described pickup process is repeated until the lifter 420 and the picker 432a move along the first direction to pick up all the wafer-level packages in their normal state positioned on the same line. After the wafer-level packages in their normal state positioned on the same line are all picked up, the wafer 12 is moved again a predetermined distance along the second direction. Then, another line that is next to the line on which the picked-up wafer-level packages have been positioned is positioned between the lifter 420 and the picker 432a. After that, the pickup process for the wafer-level packages in their normal state positioned on the next line is performed in the same way as described above.

In the meantime, the pickup process for picking up the wafer-level package 12 requires an exact alignment between the wafer-level package 12 and the pickup pad 432a. To meet such a requirement, the picker 432a may further include an electronic vision system 435 for alignment.

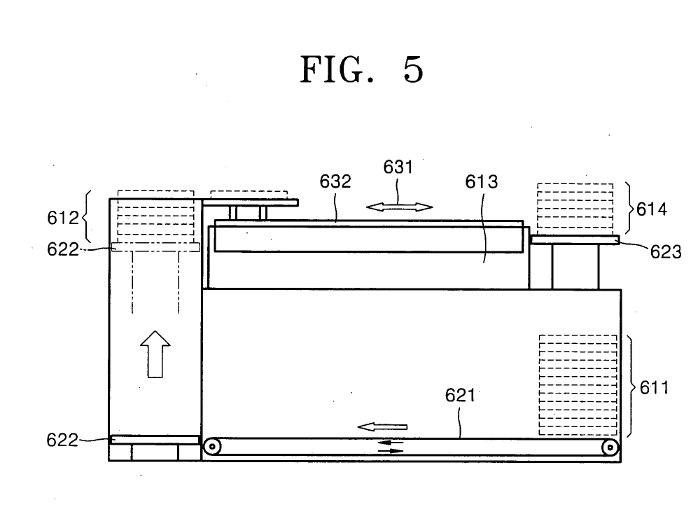

Referring to FIG. 5, the placing unit 600 for placing the wafer-level package 12′ picked up by the picker 432a includes a plate 632 that is movable in a direction of an arrow 631 by a servo motor 613 which may be located in a lower portion. The storage case where the wafer-level packages picked up by the picker 432a are stored is arranged on the plate 632. The storage case is supplied above the plate 632 by going through a plurality of operations. As illustrated by a reference numeral 611 in FIG. 5, initially the storage cases are piled and stand by in a separate stand-by space. At this state, the storage cases move along rails 621 to another stand-by space, where the storage cases are raised upward by a lift 622. The storage cases 612 standing by on the raised lift 622 are sequentially supplied onto the plate 632 one by one. The wafer-level packages picked up by the picker 432a are stored one by one in the storage cases 612 supplied onto the plate 632. If the storage cases 612 are all filled with the wafer-level packages while the above process is repeated, the storage cases 612 are stored again in a final storage tub by a lift 623 as illustrated by a reference numeral 614 of FIG. 5. Resultantly, the wafer-level packages judged as normal are stored in an inside of the storage cases 614 stored in the final storage tub.

As described above, according to embodiments of the device for manufacturing the wafer-level package and method thereof, a sawing process, a sorting process, and a placing process for the wafer-level package can be automatically performed within one device, thus a processing time reduction, a processing accuracy increase, and manpower reduction are achieved compared with the case where the processes are performed manually. Therefore, productivity can be improved.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A device for manufacturing a wafer-level package comprising:
a wafer sawing unit for discriminately cutting a wafer into wafer-level packages on a sawed wafer;
a sorting unit for sorting the wafer-level packages on the sawed wafer by judging whether each of the wafer-level packages is normal or not;
a pickup unit for picking up the normal wafer-level packages; and
a placing unit for storing the normal wafer-level packages in a storage case.

2. The device of claim 1, further comprising:
a wafer transferring unit arranged between the wafer sawing unit and the sorting unit, for transferring the sawed wafer to an inside of the sorting unit.

3. The device of claim 1, wherein the sorting unit has an electronic vision system.

4. The device of claim 1, wherein the pickup unit comprises:
a rail for moving and supporting the sawed wafer delivered from the sorting unit along a first direction;
a lifter arranged at a lower portion of the rail, for raising the wafer-level package in a pushing manner so that the wafer-level package that will be picked up can be easily detached from a tape on a lower side; and
a pickup part for picking up the wafer-level package pushed up by the lifter.

5. The device of claim 4, wherein the lifter is adapted to move in a direction perpendicular to the first direction.

6. The device of claim 4, wherein the pickup part comprises:
a guide adapted to cross the pickup unit and the placing unit; and
a picker for picking up the wafer-level package.

7. The device of claim 6, wherein the picker comprises: a frame for supporting the picker; a support inserted to an inside of the frame; and a pickup pad extended from the support and adapted to protrude downward from the frame.

8. The device of claim 6, wherein the picker is adapted to move between the pickup unit and the placing unit along the guide.

9. The device of claim 4, wherein the pickup part further comprises an electronic vision system.

10. A device for manufacturing a wafer-level package comprising:
a wafer sawing unit for discriminately cutting a wafer into wafer-level packages on a sawed wafer;
a wafer transferring unit for selectively transferring the sawed wafer to a first path and a second path;
a first sorting unit arranged on the first path, for performing a sorting process on the wafer-level packages on the sawed wafer transferred from the wafer transferring unit by judging whether each of the wafer-level packages is normal or not;
a first pickup unit arranged adjacently to the first sorting unit, to pick up the normal wafer-level packages;
a second sorting unit arranged on the second path, for performing the sorting process on the wafer-level packages on the sawed wafer transferred from the wafer transferring unit by judging whether each of the wafer-level packages is normal or not;
a second pickup unit arranged adjacently to the second sorting unit, to pick up the normal wafer-level package; and
a placing unit for storing the normal wafer-level packages in a storage case.

11. The method of claim 10, further comprising a cleaning unit to remove impurities from the wafer-level packages caused by the sawing.

12. The method of claim 10, where the wafer-level packages are fixed to each other by an adhesive tape while in the wafer transferring unit.

13. The method of claim 12, further comprising irradiating the wafer-level packages and the adhesive tape to weaken the adhesive tape.

14. A method for manufacturing a wafer-level package within an in-line system, comprising:
sawing a wafer into separate wafer-level packages;
transferring the wafer-level packages;
sorting the wafer-level packages based on whether the wafer-level packages are normal or not;
picking up normal wafer-level packages; and
storing the picked-up normal wafer-level packages in a storage case.

15. The method of claim 14, where the sorting uses an electronic vision system.

16. The method of claim 14, where the sawed wafer-level packages are selectively transferred to two or more different paths.

17. The method of claim 14, where the sawing, the transferring, the sorting, the picking up, and the storing are performed by machine.

18. The method of claim 14, further comprising cleaning the wafer-level packages to remove impurities caused by the sawing.

19. The method of claim 14, where the wafer-level packages are fixed to each other by an adhesive tape during the transferring.

20. The method of claim 19, further comprising irradiating the wafer-level packages and the adhesive tape to weaken the adhesive tape.
